(19) United States
(12) Patent Application Publication
(10) Pub. No.: US 2021/0126513 A1
(43) Pub. Date: Apr. 29, 2021

(54) POWER CONVERSION DEVICE AND POWER CONVERSION DEVICE-INTEGRATED ROTARY ELECTRIC MACHINE

(71) Applicant: Mitsubishi Electric Corporation, Tokyo (JP)

(72) Inventors: Yuji SHIRAKATA, Tokyo (JP); Yosuke UNO, Tokyo (JP); Daisuke SASAKI, Tokyo (JP); Kenta FUJII, Tokyo (JP)

(73) Assignee: Mitsubishi Electric Corporation, Tokyo (JP)

(21) Appl. No.: 16/882,961

(22) Filed: May 26, 2020

(30) Foreign Application Priority Data
Oct. 23, 2019 (JP) 2019-192405

(51) Int. Cl. H02K 11/27; H02K 11/33

(52) U.S. Cl. CPC H02K 11/27; H02K 2211/03; H02K 11/33

(57) ABSTRACT

Obtained is a power conversion device including a small-sized and low-cost fuse portion which allows overcurrent to be assuredly interrupted when being applied and allows a semiconductor element to be protected from a short-circuit fault or the like. The power conversion device includes: a circuit board; a semiconductor element mounted on the circuit board; a snubber capacitor; a snubber circuit wire which connects the snubber capacitor in parallel to the semiconductor element; and a fuse portion formed at a part of the snubber circuit wire.

### BACKGROUND OF THE INVENTION

### 1. Field of the Invention

The present disclosure relates to a power conversion device and a power conversion device-integrated rotary electric machine.

### 2. Description of the Background Art

Many automobiles, such as electric automobiles and hybrid automobiles, that use motors for vehicle running have been developed. Power conversion devices for driving these motors supply high-voltage drive power to drive circuits of the motors, with batteries serving as power supplies.

Therefore, such power conversion devices for driving the motors have become increasingly important as key devices in the field of power electronics.

In such a power conversion device, fuses are connected to wires in order to protect power semiconductor elements from overcurrent due to a short-circuit fault among the wires or the like, and the wires are disconnected so as to deal with overcurrent. Chip-type overcurrent interrupting fuses are generally used as such fuses, but are expensive. Thus, for example, the following interrupting methods are proposed to reduce cost.

A small-width portion is formed at a part of a power lead connected to a main electrode of a semiconductor element, so as to be used as a fuse portion (Patent Document 1). When overcurrent flows in the fuse portion provided to the power lead of the semiconductor element, the fuse melts, whereby overcurrent can be interrupted.

A configuration in which a main circuit wire connected to a semiconductor element is provided and a bus bar is connected to the main circuit wire so as to exert spring force to the main circuit wire, is described (Patent Document 2). When overcurrent flows in the main circuit wire, a sealing resin maintaining the spring force ruptures, whereby the main circuit wire is separated.

Patent Document 1: Japanese Laid-Open Patent Publication No. 2003-068967

Patent Document 2: Japanese Laid-Open Patent Publication No. 2008-153463

In Patent Document 1, the fuse portion is provided to the power lead for supplying power to the semiconductor element. Thus, when overcurrent is applied to the semiconductor element, the fuse portion melts, whereby current can be interrupted. However, the temperature of the melting portion becomes very high, and thus a problem arises in that contact or connection may occur at the fuse portion again.

Meanwhile, in the case of the configuration of Patent Document 2 in which the connection of the bus bar is maintained by the spring force, a problem arises in that a large area for installing a device having intense spring force is necessary and force is exerted to the joined portion, and another problem arises in terms of ensuring long-term reliability.

### SUMMARY OF THE INVENTION

The present disclosure has been made to solve the above problems, and an object of the present disclosure is to obtain a power conversion device including a small-sized and low-cost fuse portion which allows overcurrent to be assuredly interrupted and allows a semiconductor element to be protected from a short-circuit fault or the like.

A power conversion device according to the present disclosure includes: a circuit board; a semiconductor element mounted on the circuit board; a snubber capacitor; a snubber circuit wire which connects the snubber capacitor in parallel to the semiconductor element; and a fuse portion formed at a part of the snubber circuit wire.

In the power conversion device according to the present disclosure, the fuse portion which is small-sized and low-cost allows overcurrent to be assuredly interrupted and allows the semiconductor element to be protected from a short-circuit fault or the like.

### BRIEF DESCRIPTION OF THE DRAWINGS

FIG. 1 is a circuit diagram of a power conversion device according to a first embodiment;

FIG. 2 is a perspective view of a power conversion module in the first embodiment;

FIG. 3 is a perspective view of the power conversion module from which a cover is detached, in the first embodiment;

FIG. 4 is a sectional view of the power conversion module in the first embodiment;

FIG. 5 is an exploded view of the power conversion module in the first embodiment;

FIG. 6 illustrates the shape of a fuse portion in the first embodiment;

FIG. 7 illustrates specific examples of the fuse portion in the first embodiment;

FIG. 8 illustrates the shape of a fuse portion in the first embodiment;

FIG. 9 illustrates specific examples of the fuse portion in the first embodiment;

FIG. 10 illustrates a schematic configuration of a power conversion device-integrated rotary electric machine according to the first embodiment; and

FIG. 11 illustrates the shape of a fuse portion in a second embodiment.

### DETAILED DESCRIPTION OF THE PREFERRED EMBODIMENTS OF THE INVENTION

In the descriptions of the embodiments and the drawings, parts denoted by the same reference characters indicate the same or corresponding parts.

### First Embodiment

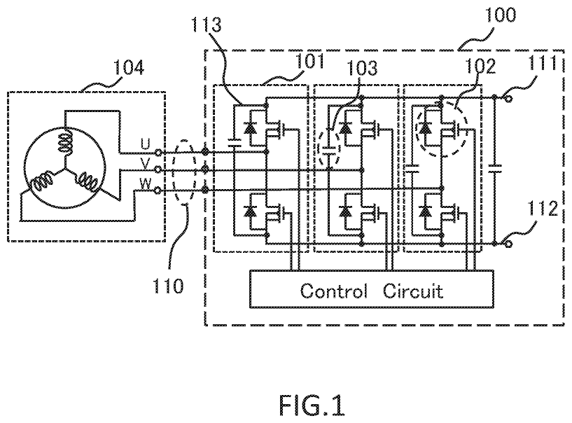

A power conversion device according to a first embodiment will be described with reference to FIG. 1 to FIG. 9.

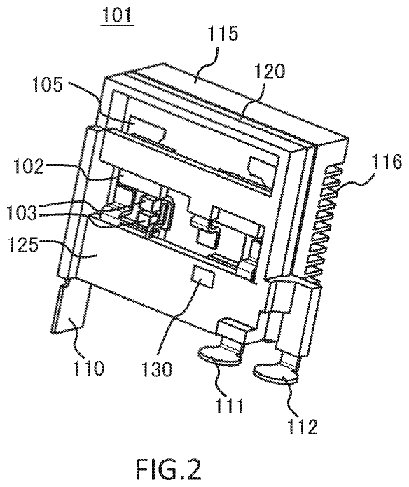

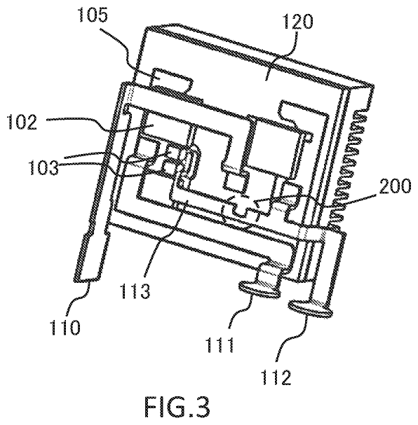

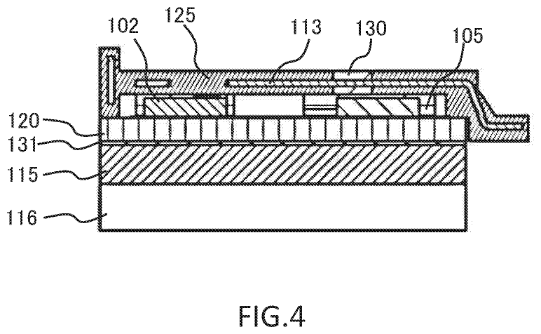

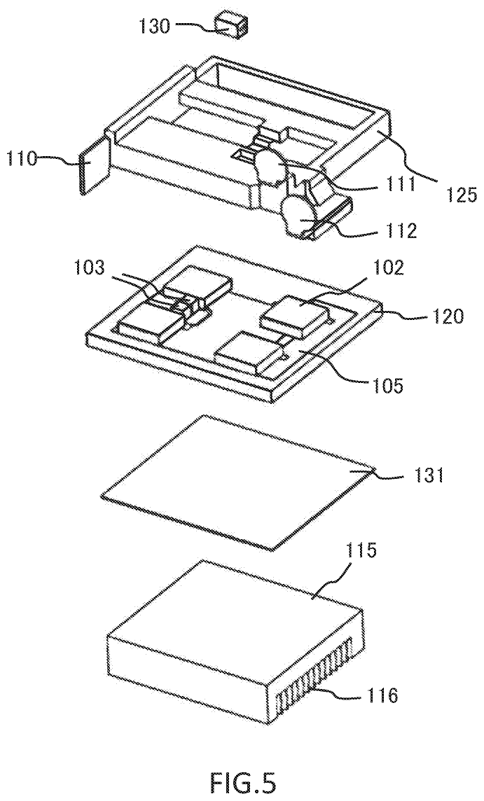

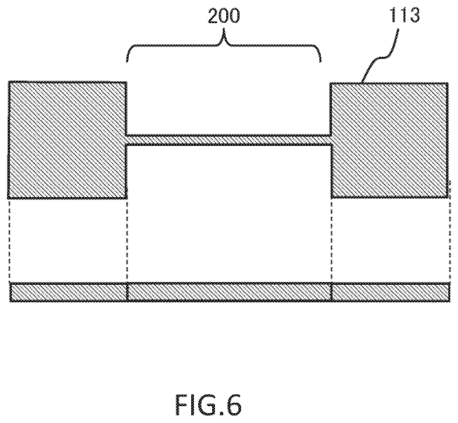

FIG. 1 is a circuit diagram of a power conversion device 100 according to the first embodiment. FIG. 2 is a perspective view of a power conversion module 101 composing the power conversion device 100. FIG. 3 is a perspective view of an internal configuration of the power conversion module 101 from which a cover 125 is detached. FIG. 4 is a sectional view taken along a line that crosses a resin material 130 of the power conversion module 101 shown in FIG. 2. FIG. 5 is an exploded view in which the power conversion module 101 is exploded into main constituent members. FIG. 6 to FIG. 9 illustrate shapes and specific examples of a fuse portion 200.

<Configuration of Power Conversion Device>

First, the configuration of the power conversion device 100 according to the present first embodiment will be described.

FIG. 1 shows the power conversion device 100 and a rotary electric machine 104. The power conversion device 100 according to the first embodiment is composed of a plurality of the power conversion modules 101. Each power conversion module 101 includes: semiconductor elements 102 each of which performs switching based on a signal from a control circuit; and a snubber circuit wire 113 which forms a snubber circuit and on which a snubber capacitor 103 is disposed so as to be connected in parallel to the semiconductor elements 102.

Although not shown in the circuit diagram in FIG. 1, the fuse portion 200 is obtained by forming a slit or the like in the snubber circuit wire 113 so as to have a small sectional area, as described later.

FIG. 2 is a perspective view of the power conversion module 101 in the first embodiment. FIG. 3 shows an internal configuration of the power conversion module 101 on which the semiconductor elements 102 and various wires are formed, with the cover 125 of the power conversion module 101 being detached.

As shown in the sectional view in FIG. 4 and the exploded view in FIG. 5, in the power conversion module 101, a circuit board 120 is disposed on a heat sink 115 having heat-dissipating fins 116 formed thereon, with a heat-dissipating member 131 being interposed therebetween. On the circuit board 120, a conductor pattern 105 is formed, and the semiconductor elements 102 and the snubber capacitor 103 are mounted.

Heat generated by the semiconductor elements 102 and the like during operation can be dissipated from the fins 116 to the outside by the heat-dissipating member 131 and the heat sink 115.

As shown in FIG. 3 and the like, the wires include: a positive wire 111 and a negative wire 112 which receive power supplied from a battery or the like to the power conversion module 101; and an output wire 110 through which the power is converted and outputted in the power conversion module 101. The wires further include the snubber circuit wire 113 for connecting the snubber capacitor 103 in parallel to the semiconductor elements 102. In FIG. 5, the snubber circuit wire 113 is located in the cover 125 and is not shown.

The various wires are connected to terminal portions of the semiconductor elements 102 and the snubber capacitor 103 mounted on the circuit board 120. Extended portions of the wires that are led to the outside of the power conversion module 101 are located apart from the surface of the circuit board 120 and the surfaces of the semiconductor elements 102 so as to maintain a gap therefrom.

The cover 125 formed of resin is attached to the circuit board 120.

The wires can be formed to be integrated with the cover 125 by any of insert molding, outsert molding, a lamination method, and the like being performed on the resin that is to form the cover 125. Alternatively, either of wires having insulation tapes wound therearound and wires having insulation coatings formed on surfaces thereof by applying powder on the surfaces, may be attached to the cover 125 and used.

The snubber circuit wire 113 connects the snubber capacitor 103 in parallel to the semiconductor elements 102, and the fuse portion 200 is formed at a part of the snubber circuit wire 113. As shown as an example by being enclosed by the broken line in FIG. 3, the fuse portion 200 is obtained by forming a slit 202 in the snubber circuit wire 113.

Although described in detail with reference to FIG. 6 to FIG. 9, the fuse portion 200 is obtained by forming a punched hole 201 or the slit 202 in a part of the snubber circuit wire 113 so as to locally have a small sectional area. That is, the fuse portion 200 is formed so as to have a smaller sectional area than the other portion of the snubber circuit wire 113.

In such a power conversion module 101, when the snubber capacitor 103 is normally operated, it is possible to prevent rapid overvoltage due to switching by the semiconductor elements 102. When the snubber capacitor 103 is abnormal, overcurrent is applied from the battery. In this case, the temperature of the fuse portion 200 increases and the fuse portion 200 melts owing to overcurrent, whereby overcurrent can be assuredly interrupted, and damages to the semiconductor elements 102, the battery, and the like can be prevented.

The fuse portion 200 is coated with the resin material 130, and the fuse portion 200 can also be formed to be integrated with the cover 125. As shown in FIG. 2 to FIG. 4 and the like, an opening is formed at a portion, of the cover 125, that corresponds to the fuse portion 200, and the resin material 130 with which the fuse portion 200 is coated is disposed in the opening.

The heat sink 115 and the fins 116 used in the present first embodiment are required to be formed of a material that allows dissipation of heat generated by the semiconductor elements 102 during operation. Specifically, the material is preferably a material having a thermal conductivity not less than 80 W/mK, such as aluminum or an aluminum alloy.

As each semiconductor element 102, a power field effect transistor, i.e., a metal oxide semiconductor field effect transistor (MOSFET), an insulated gate bipolar transistor (IGBT), or the like may be used. These transistors are used for power conversion for devices such as a motor, and control rated current at several amperes to several hundreds of amperes.

As the raw material of the semiconductor element 102, not only silicon (Si) but also silicon carbide (SiC), gallium nitride (GaN), or the like may be used.

Although a ceramic capacitor is used as the snubber capacitor 103 in the present first embodiment, the snubber capacitor 103 is not limited thereto. Another type of capacitor can also be used as long as overvoltage can be absorbed at the time of a break of the semiconductor element 102. However, when the size, the heat resisting property, and the like of the capacitor are taken into consideration, ceramic capacitors are considered to be most suitable.

A substrate used for the circuit board 120 may be a printed substrate in which ordinary glass fiber is used as a core material, a ceramic substrate, an aluminum core substrate, or the like. An insulating material used for the surface of the substrate may be a resin material having a thermal conductivity of 1 W/mK to several tens of W/mK, such as urethane, silicone, or epoxy.

The semiconductor element 102 and the like can be mounted on the circuit board 120 by a connection method that allows electrical and thermal connection to be ensured in a predetermined space, such as a method using a conductive adhesive, soldering, diffusion bonding, ultrasonic welding, or laser welding.

As the material of the positive wire 111, the negative wire 112, and the like, a metal material having low electric resistivity such as copper or aluminum may be used.

The resin material 130 with which the fuse portion 200 formed on the snubber circuit wire 113 is coated, is formed of a material that is effective in preventing metal pieces or the like from being scattered and in exhibiting an arc-extinguishing effect when the fuse portion 200 melts.

For preventing such scatter, the Young's modulus of the resin material 130 is preferably not less than 10 MPa and less than 100 MPa. If the Young's modulus is less than 10 MPa, the resin material 130 has insufficient strength and sometimes cannot confine scattered pieces. Meanwhile, if the Young's modulus is not less than 100 MPa, the resin material 130 is sometimes damaged simultaneously with the fuse portion 200 at the time of the melting, and the metal pieces sometimes cannot be prevented from being scattered.

From the viewpoint of the arc-extinguishing effect, for example, silicone rubber and silicone gel are suitable for the resin material 130. If an electronic component is not located near the fuse portion 200 but located apart from the fuse portion 200 at a certain distance, influence of such scatter and influence of an arc can be reduced.

<Shape of Fuse Portion>

Next, the shape of the fuse portion 200 will be described.

Shapes and specific examples of the fuse portion 200 will be described with reference to FIG. 6 to FIG. 9. These drawings show examples of the shape that allows implementation of the fuse portion 200, and a shape other than those shown in these drawings also allows exhibition of the same advantageous effect as that in the present first embodiment as long as the fuse portion 200 is formed so as to have a smaller sectional area than the other portion of the snubber circuit wire 113.

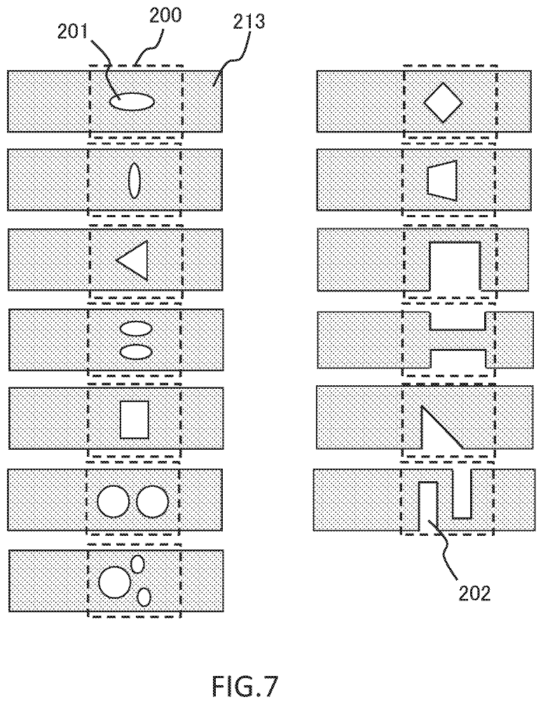

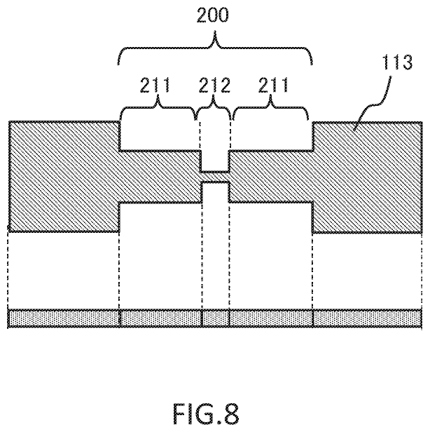

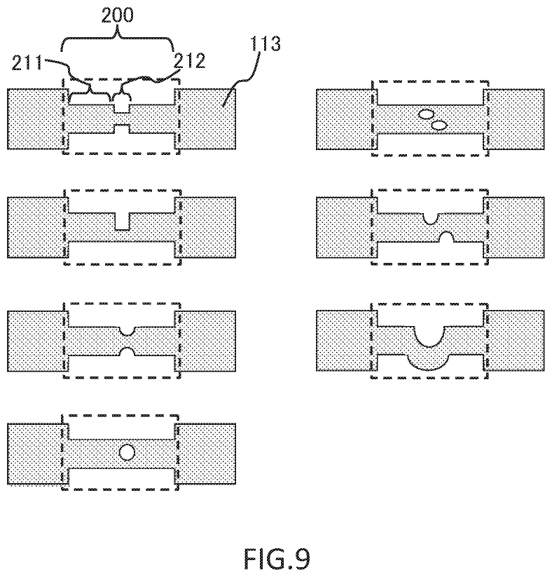

FIG. 6 illustrates an example of the fuse portion 200 formed on the snubber circuit wire 113. FIG. 7 illustrates specific examples in each of which the fuse portion 200 is obtained by forming a punched hole 201 or a slit 202 in the snubber circuit wire 113. FIG. 8 illustrates an example of a fuse portion 200, in which the sectional area of the snubber circuit wire 113 is changed in two stages. FIG. 9 illustrates specific examples of the fuse portion 200, in each of which the sectional area is changed in two stages.

FIG. 7 and FIG. 9 respectively illustrate 13 types of specific examples and seven types of specific examples. However, the shape is not limited to the shapes in these specific examples as long as the fuse portion 200 is formed so as to have a smaller sectional area than the other portion of the snubber circuit wire 113 as described above.

The fuse portion 200 shown in each of these drawings is obtained by forming either of the punched hole 201 and the slit 202 in a part of the snubber circuit wire 113. The fuse portion 200 is formed such that the sectional area of the snubber circuit wire 113 is sufficiently larger than the sectional area of the fuse portion 200, the ratio of the sectional area of the snubber circuit wire 113 to the sectional area of the fuse portion 200 being, for example, 9:1.

Since either of the punched hole 201 and the slit 202 is formed at a part of the snubber circuit wire 113 and the sectional area of the fuse portion 200 is made smaller than that of the other portion of the snubber circuit wire 113, the density of current in the fuse portion 200 increases. Furthermore, since the sectional area is made small, the thermal resistance increases as indicated in the following formula. Accordingly, the density of heat generated when current flows increases, and the heat dissipation property deteriorates. Thus, the temperature of the fuse portion 200 locally increases and can be melted.

Thermal resistance=length/(thermal conductivity×sectional area) (1)

If the snubber capacitor 103 suffers a short-circuit fault or the like for some reason and overcurrent is applied from the battery to the snubber circuit wire 113, the temperature of a portion of the fuse portion 200 that has the smallest sectional area rapidly increases in a short time. When the temperature rises to the melting temperature of the metal as a result of the rapid increase, the fuse portion 200 melts.

If the fuse portion 200 of the snubber circuit wire 113 is coated with the resin material 130, the arc-extinguishing effect is exhibited by the resin material 130 at the time of the melting so that an arc generated owing to the melting is extinguished, whereby current can be interrupted. In addition, if the width and the length of the fuse portion 200 are changed, the relationship between current and time required for causing the melting can be adjusted, and a desired melting characteristic can be obtained.

In the present first embodiment, the fuse portion 200 which melts so as to deal with overcurrent is obtained by forming either of the punched hole 201 and the slit 202 in the snubber circuit wire 113 so as to make the sectional area of the fuse portion 200 smaller than that of the other portion of the snubber circuit wire 113. However, the same advantageous effect can be obtained also if a metal material having a higher electric resistivity or a lower melting temperature than the metal material forming the other portion of the snubber circuit wire 113 is joined to a part of the snubber circuit wire 113 and used. Alternatively, the present disclosure can be implemented also by combining the configuration in which either of the metal material having a higher electric resistivity and the metal material having a lower melting temperature is used and the configuration in which the sectional area of the fuse portion 200 is made smaller than that of the other portion of the snubber circuit wire 113.

As described above, in the present first embodiment, either of the punched hole 201 and the slit 202 is formed in the snubber circuit wire 113, thereby forming, at a part of the snubber circuit wire 113, the fuse portion 200 having a smaller sectional area. In addition, the fuse portion 200 is coated with the resin material 130 for exhibiting the arc-extinguishing effect, such as silicone rubber or silicone gel, so that an arc generated owing to the melting is extinguished, whereby current is assuredly interrupted. Accordingly, a short-circuit fault in the power conversion device 100 due to overcurrent can be prevented.

In the present first embodiment, no new overcurrent interrupting fuse needs to be added, and thus the number of components does not increase and the number of components to be mounted does not increase either, whereby high productivity can be achieved.

Since the fuse portion 200 is formed on the snubber circuit wire 113, the rigidity of the snubber circuit wire 113 decreases. Thus, thermal stress to be exerted owing to a change in the temperature decreases. Accordingly, stress to be exerted on a joined portion of the circuit board 120 or the like can be reduced, and the reliability can also be expected to be improved.

Since the snubber capacitor 103 is used, current hardly flows in the snubber circuit wire 113, and influence of overvoltage at the time of switching by the semiconductor element 102 can also be mitigated. Since current flows in the case of a fault of the snubber capacitor 103, there is a significant difference between current flowing in the case where the snubber capacitor 103 suffers a fault and current flowing in the case where the snubber capacitor 103 is normal. Thus, it can be said to be easy to design a fuse portion 200 that melts only in the case of a fault.

On the other hand, if the fuse portion 200 is formed on a wire such as the positive wire 111 or the negative wire 112 that is intended for supplying power and through which predetermined current flows in a normal case, there is a small difference between overcurrent flowing in the case of a fault and current flowing in a normal case. Thus, it becomes difficult to design the fuse.

Therefore, it can be said that the fuse portion 200 is not suitably formed on the positive wire 111, the negative wire 112, or the like for supplying power, and is suitably formed on the snubber circuit wire 113 on which the snubber capacitor 103 is disposed.

As shown in FIG. 6 to FIG. 9, the shape of each of the punched hole 201 and the slit 202 in the fuse portion 200 can be a circle, an ellipse, a triangle, a quadrangle, a rhombus, a trapezoid, or the like. Alternatively, these shapes can be combined. If the sectional area is changed in two stages as shown in FIG. 8 and FIG. 9, the shape of each of a first slit 211 and a second slit 212 can also be a circle, an ellipse, a quadrangle, or the like.

As described above, in the power conversion device 100 according to the present first embodiment, the power semiconductor element 102 can be protected from influence of overcurrent from the battery also in the case where the snubber capacitor 103 suffers a short-circuit fault.

The power conversion device 100 according to the present first embodiment can be used as a device for controlling a rotary electric machine that is mounted in a vehicle and that generates electricity for and drives an engine.

The power conversion device 100 is connected to a battery (DC power supply) for the vehicle, converts power, and supplies AC current to a stator winding of the rotary electric machine.

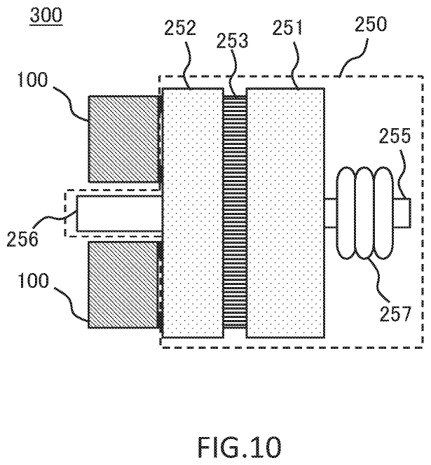

FIG. 10 is a schematic configuration diagram of a power conversion device-integrated rotary electric machine 300 in which the power conversion device 100 described in the present first embodiment and a rotary electric machine body 250 are integrated with each other.

In FIG. 10, a pulley 257 is fixed to a shaft 255 extending to one end of the rotary electric machine body 250, the pulley side of the rotary electric machine body 250 is referred to as a front side, and the side opposite to the pulley side is referred to as a rear side.

A stator 253 is fixed to a front-side housing 251 and a rear-side housing 252, and a rotor (not shown) is rotatably supported in the two housings 251 and 252. The pulley 257 is, as described above, fixed to the shaft 255 extending from the rotor to the front side, and power is transmitted to the engine by a torque transmission belt (not shown) attached to the pulley 257.

The power conversion device 100 including the power conversion module 101 and the like is disposed on the rear-side surface of the rear-side housing 252, and a space that allows a shaft 256 to be inserted therethrough is formed at a center portion of the power conversion device 100.

Here, the wires and the like are omitted for simplification of the description. In addition, a protective cover used on an outer circumferential portion of the power conversion device 100 is also omitted.

In the power conversion device-integrated rotary electric machine 300 shown in this drawing, the power conversion device 100 including the fuse portion 200 and the rotary electric machine body 250 are integrated with each other, and thus no external fuse is needed, and downsizing can be achieved. Furthermore, the number of components does not need to be increased either, and thus the mounting process can be simplified, and high productivity can be achieved.

### Second Embodiment

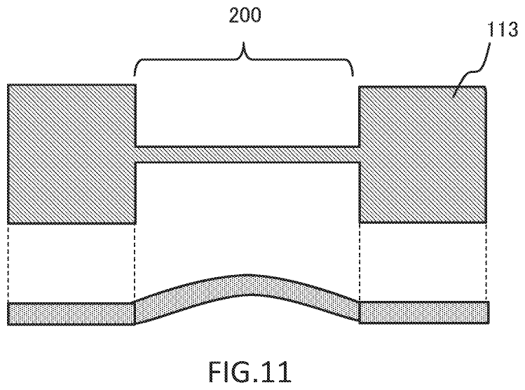

The shape of a fuse portion 200 of a snubber circuit wire 113 in the present second embodiment is shown in FIG. 11. The upper side of FIG. 11 is a plan view of the snubber circuit wire 113, and the lower side of FIG. 11 is a side view thereof. The power conversion device 100 and the power conversion module 101 which use the snubber circuit wire 113 in the present second embodiment, and the like have basically the same structures as those described in the first embodiment.

The fuse portion 200 used in the present second embodiment is not formed on the same plane as the plane of the snubber circuit wire 113, but projects upward in FIG. 11 as shown in the side view on the lower side of FIG. 11. In a state where the snubber circuit wire 113 is disposed on the circuit board 120 composing the power conversion module 101, the fuse portion 200 is disposed so as to project in a direction away from electronic components such as the semiconductor element 102 mounted on the circuit board 120. Accordingly, scattered pieces are less likely to be scattered to the circuit board 120 side at the time of the melting, whereby the electronic components can be protected.

The fuse portion 200 can be formed in a projecting shape simultaneously with a step of forming either of the punched hole 201 and the slit 202 in the fuse portion 200. Alternatively, the fuse portion 200 can be formed in a projecting shape in a step of forming the cover 125 and each wire integrally with each other by insert molding or the like, with use of the resin material 130 for the cover 125.

As described above, the fuse portion 200 is formed so as to project in a direction away from the circuit board 120, and thus the electronic components and the like can be protected from scattered pieces at the time of the melting, whereby the reliability can be improved.

Also as for the power conversion device 100 according to the present second embodiment, the rotary electric machine 104 and the power conversion device 100 can be integrated with each other, thereby obtaining the power conversion device-integrated rotary electric machine 300, as shown in the schematic configuration in FIG. 10.

Since the power conversion device-integrated rotary electric machine 300 is obtained by integrating the power conversion device 100 including the fuse portion 200 and the rotary electric machine 104 with each other, no external fuse is needed, and downsizing can be achieved. Furthermore, the number of components does not need to be increased either, and thus the mounting process can be simplified, and high productivity can be achieved.

Although the disclosure is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the specification of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

100 power conversion device
101 power conversion module
102 semiconductor element
103 snubber capacitor
104 rotary electric machine
105 conductor pattern
110 output wire
111 positive wire
112 negative wire
113 snubber circuit wire
115 heat sink
116 fin
120 circuit board
125 cover
130 resin material
131 heat-dissipating member
200 fuse portion
201 punched hole
202 slit
211 first slit
212 second slit
250 rotary electric machine body
251 front-side housing
252 rear-side housing
253 stator
255 shaft
256 shaft
257 pulley
300 power conversion device-integrated rotary electric machine

What is claimed is:

1. A power conversion device comprising:
a circuit board;
a semiconductor element mounted on the circuit board;
a snubber capacitor;
a snubber circuit wire which connects the snubber capacitor in parallel to the semiconductor element; and
a fuse portion formed at a part of the snubber circuit wire.

2. The power conversion device according to claim 1, wherein the fuse portion has a smaller sectional area than another portion of the snubber circuit wire.

3. The power conversion device according to claim 1, wherein the fuse portion is formed of a metal material that has a lower melting temperature than another portion of the snubber circuit wire.

4. The power conversion device according to claim 2, wherein the fuse portion is formed of a metal material that has a lower melting temperature than another portion of the snubber circuit wire.

5. The power conversion device according to claim 1, wherein the fuse portion is formed of a metal material that has a higher electrical resistance than another portion of the snubber circuit wire.

6. The power conversion device according to claim 2, wherein the fuse portion is formed of a metal material that has a higher electrical resistance than another portion of the snubber circuit wire.

7. The power conversion device according to claim 3, wherein the fuse portion is formed of a metal material that has a higher electrical resistance than another portion of the snubber circuit wire.

8. The power conversion device according to claim 1, wherein the snubber capacitor is a ceramic capacitor.

9. The power conversion device according to claim 2, wherein the snubber capacitor is a ceramic capacitor.

10. The power conversion device according to claim 3, wherein the snubber capacitor is a ceramic capacitor.

11. The power conversion device according to claim 4, wherein the snubber capacitor is a ceramic capacitor.

12. The power conversion device according to claim 1, wherein the snubber circuit wire is located apart from the circuit board.

13. The power conversion device according to claim 1, wherein the fuse portion is located apart from the semiconductor element mounted on the circuit board.

14. The power conversion device according to claim 13, wherein the fuse portion is disposed so as to project from the snubber circuit wire in a direction away from the circuit board.

15. The power conversion device according to claim 1, wherein the fuse portion is coated with a resin material having an arc-extinguishing effect.

16. The power conversion device according to claim 15, wherein a Young's modulus of the resin material is not less than 10 MPa and less than 100 MPa.

17. A power conversion device-integrated rotary electric machine in which the power conversion device according to claim 1 and a rotary electric machine are integrated with each other.

18. A power conversion device-integrated rotary electric machine in which the power conversion device according to claim 2 and a rotary electric machine are integrated with each other.

19. A power conversion device-integrated rotary electric machine in which the power conversion device according to claim 3 and a rotary electric machine are integrated with each other.

20. A power conversion device-integrated rotary electric machine in which the power conversion device according to claim 4 and a rotary electric machine are integrated with each other.
